(19) United States
(12) Patent Application Publication
(10) Pub. No.: US 2019/0250681 A1
(43) Pub. Date: Aug. 15, 2019

(54) SOLAR POWERED LAPTOP COMPUTER COOLING SYSTEM

(71) Applicant: Regina Kirch, London (GB)

(72) Inventor: Regina Kirch, London (GB)

(21) Appl. No.: 16/275,992

(22) Filed: Feb. 14, 2019

Related U.S. Application Data
(60) Provisional application No. 62/628,386, filed on Feb. 9, 2018.

(51) Int. Cl. G06F 1/20; G06F 1/16; H02J 7/35; H02J 7/00; H05K 7/20

(52) U.S. Cl. CPC G06F 1/203; G06F 1/1616; G06F 1/1635; H05K 7/20209; H02J 7/35; H02J 7/0068; H05K 7/20172; G06F 1/206

(57) ABSTRACT

Disclosed embodiments provide a solar powered laptop computer cooling system. This enables improved reliability in hot, outdoor environments. Since the disclosed embodiments utilize solar power, they do not adversely impact the battery life of the laptop itself. One or more fans are disposed below the laptop and provide additional airflow to keep the laptop computer operating within an appropriate temperature range.

### CLAIM OF PRIORITY

This application claims the priority of U.S. Ser. No. 62/628,386 filed on Feb. 9, 2018, the contents of which are fully incorporated herein by reference.

### FIELD OF THE EMBODIMENTS

The disclosed embodiments relate generally to laptop computer cooling systems.

### BACKGROUND

With the increase in use and proliferation of technology around the world, people across a wide array of demographics are using laptops daily for personal and professional operations. The advancements in the field of portable electronics has not only created efficiencies for people and increased information sharing, but it has allowed for greater flexibility in terms of where a person works and when. As a direct consequence of this, the work/life balance of many staff members has been enhanced, leading numerous organizations to also see a significant impact on work output for the better. The lightweight design and consistent improvements to the speed, battery life, and other components of laptops have made them a staple across such office communities and beyond.

That being said, laptops do come with their flaws. One of the most notable, universal concerns with laptops (and portable electronics generally) is the fact that they need to be protected when a person is in a high temperature environment. Unfortunately, this reduces the locations in which a person can work, excluding the most pleasant locales where studies have shown that people tend to be happiest, which is places in direct light. It is scientifically proven that people are more positive and energetic in bright settings, and while such a “workspace” could lend itself to boosting morale and helping to improve the quality and quantity of work output, it is not feasible to use a laptop in such a setting. It is therefore desirable to have improvements in laptop computer cooling systems.

### SUMMARY

In one embodiment, there is provided a laptop computer cooling system, comprising: a solar panel, the solar panel attachable to a rear side of a display of a laptop computer; a fan enclosure, the fan enclosure attachable to a base portion of the laptop computer; wherein the fan enclosure comprises one or more fans configured to operate from power provided by the solar panel.

Embodiments are further provided wherein the fan enclosure comprises two fans.

Embodiments are further provided wherein each fan of the fan enclosure comprises four blades.

Embodiments are further provided wherein the fan enclosure further comprises a rechargeable battery, configured and disposed to receive power from the solar panel, and to provide power to each fan of the fan enclosure.

Embodiments are further provided wherein the rechargeable battery comprises a nickel cadmium battery.

Embodiments are further provided wherein the rechargeable battery comprises a lithium ion battery.

Embodiments further provide a temperature activated switch, configured and disposed to activate each fan of the fan enclosure upon detecting a temperature above a predetermined threshold.

Embodiments are further provided, wherein the predetermined threshold is a temperature ranging from 50 degrees Celsius to 75 degrees Celsius.

Embodiments are further provided comprising one or more side vents disposed in the lower component (fan enclosure).

Embodiments are further provided comprising a perforated surface disposed on a bottom surface of the fan enclosure.

Embodiments are further provided, wherein the two fans are configured to rotate at a speed ranging from 200 revolutions per minute to 3,000 revolutions per minute.

Embodiments are further provided, wherein the two fans comprise a first fan and a second fan, and wherein the first fan and second fan are both configured to draw air into the side vents.

Embodiments are further provided, wherein the two fans comprise a first fan and a second fan, and wherein the first fan and second fan are both configured to push air out of the side vents.

Embodiments are further provided, wherein the two fans comprise a first fan and a second fan, wherein the first fan is configured to draw air into of one of the side vents and wherein the second fan is configured to push air out of one of the side vents.

Additional embodiments provide a cooling case for a laptop comprising: two parts; wherein the parts are made of plastic material; a cooling fan; solar panels as the only source of power; and tubular clips to connect the two parts.

### BRIEF DESCRIPTION OF THE DRAWINGS

FIG. 1A is an external-facing side of an upper component of an embodiment of the present invention.

FIG. 1B is a user-facing side of an upper component of an embodiment of the present invention.

FIG. 2A is a bottom-facing side of a lower component of an embodiment of the present invention.

FIG. 2B is a top-facing side of a lower component of an embodiment of the present invention.

FIG. 3 is a perspective view of an embodiment of the present invention.

FIG. 4 is a perspective view of an alternative embodiment of the present invention.

FIG. 5 is a schematic view of a lower component of an alternative embodiment of the present invention.

FIG. 6 is a bottom-up view of a lower component of an alternative embodiment of the present invention.

FIG. 7A is a side cutaway view of a lower component of an alternative embodiment of the present invention configured for convergent airflow.

FIG. 7B is a side cutaway view of a lower component of an alternative embodiment of the present invention configured for divergent airflow.

FIG. 7C is a side cutaway view of a lower component of an alternative embodiment of the present invention configured for pass-through airflow.

The drawings are not necessarily to scale. The drawings are merely representations, not necessarily intended to portray specific parameters of the invention. The drawings are intended to depict only example embodiments of the invention, and therefore should not be considered as limiting in scope. In the drawings, like numbering may represent like elements. Furthermore, certain elements in some of the figures may be omitted, or illustrated not-to-scale, for illustrative clarity.

### DETAILED DESCRIPTION

Disclosed embodiments provide a solar powered laptop computer cooling system. This enables improved reliability for laptop functionality in hot, outdoor environments. Since the disclosed embodiments utilize solar power, they do not adversely impact the battery life of the laptop itself.

Disclosed embodiments are shown in a laptop cooling application, although other iterations could be crafted on the same premise for electronic devices such as tablets and mobile phones. In embodiments, the structure of the product is in two clear, plastic pieces—one for the top/screen side of a laptop and the other for the bottom/keyboard side. When a laptop is opened for use, the component of the case inclusive of the solar panels is placed on the top side of the laptop (panels facing outwards to absorb the light energy). The side of the top plastic case covering the laptop screen will be clear since the only necessity of the whole top half of the laptop being enclosed is to contain the airflow once the product initiates the cooling mechanism. Then, the other plastic covering is placed on the bottom of the laptop, which will clip into the top case. The side with plastic fans should sit below the keyboard and the side with the soft plastic covering the keyboard (in embodiments, a soft plastic portion used in order to trap in cool air but also enable a person to type). In embodiments, once the two plastic pieces are clipped into each other, the case will trap in air, so when it is brought out into the light, the cooling mechanism will proliferate across the device. This will drastically reduce the potential for overheating and thus allow a person to utilize the laptop in such climates where an electronic device typically would stop functioning due to the high temperatures.

In order to bring clarity to what the present invention would look like in structural and functional terms, please refer to the drawings associated with this disclosure, details of which are described below.

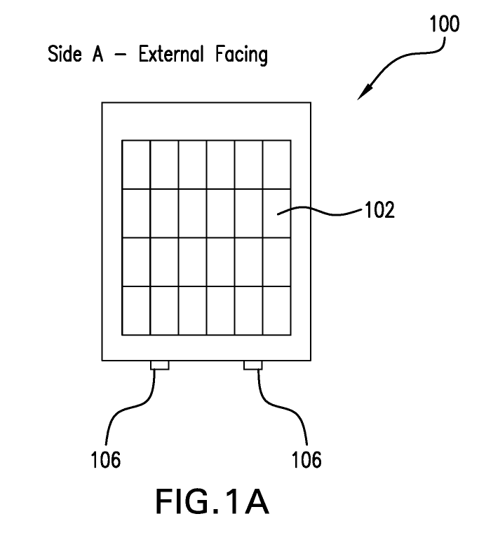

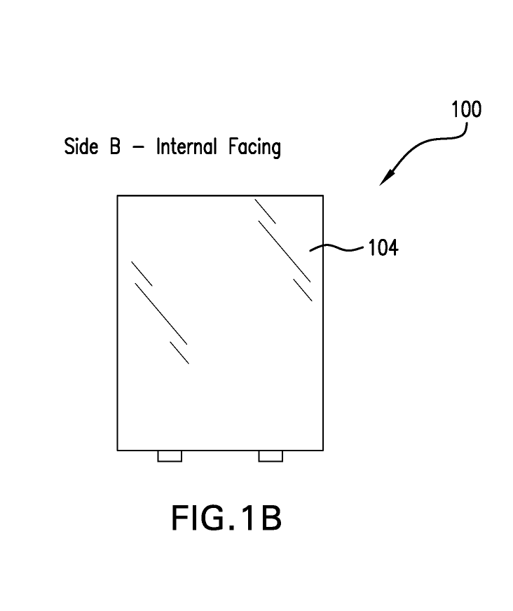

FIG. 1A and FIG. 1B show an image of one of two parts of an embodiment of the present invention, which is the upper component 100 of the case that would attach to the side of the laptop with a screen. FIG. 1A shows the external facing side of the device that has solar panels 102 while FIG. 1B shows the internal facing (user-facing) side that is merely clear plastic 104 for ease of viewing the laptop's screen. Two rectangles 106 are on the bottom of the device and indicate where the upper and lower components are connected.

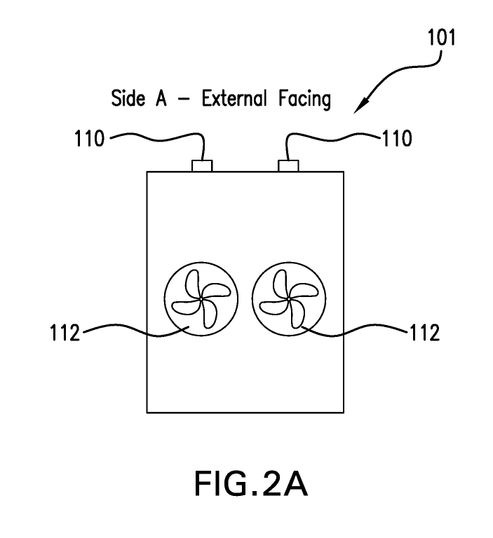

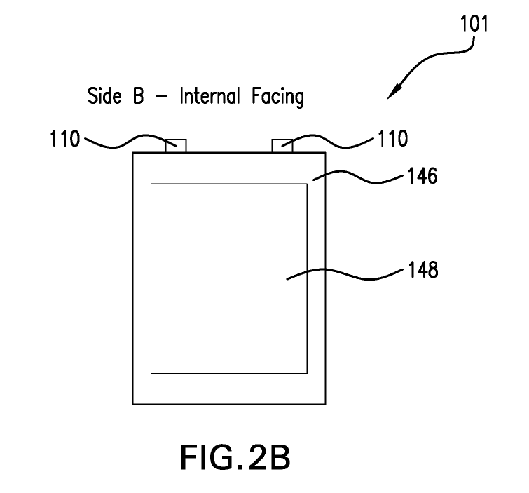

FIG. 2A is an image of a lower component 101 of disclosed embodiments, which is the piece of the case that attaches to the main chassis of the laptop with a keyboard. The lower component serves as a fan enclosure. FIG. 2A shows an external facing (bottom-facing) side of the device that encompasses the plastic fans 112 powered by the solar energy that serve as a cooling mechanism. FIG. 2B is the internal facing (user-facing) side 146 that may be comprised of mostly hard clear plastic, but with a soft plastic region 148 that covers the keyboard in order to enable one to type while the device is being used. Two rectangles 110 are on the top of the device and indicate where the upper and lower components attach.

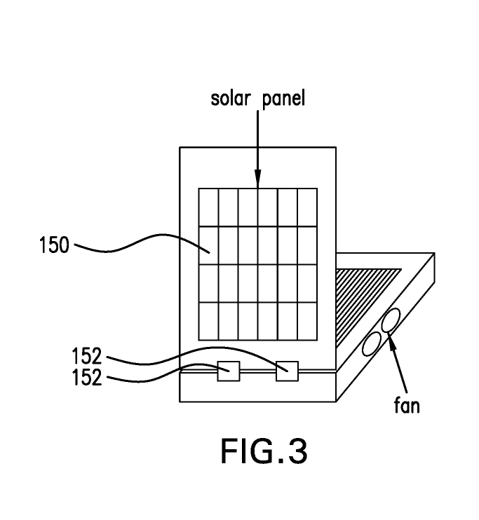

FIG. 3 displays an embodiment of the invention when the two parts are attached on a laptop (in other words, a holistic image of the invention). The angle of the drawing is from the back of the laptop when it is opened, with the solar panel 150 illustrated as completely visible in order to capture the solar energy on the back of the laptop and the fan shown underneath the device. FIG. 3 shows rectangular, hollow clips 152 connecting the lower and upper components, allowing air flow through these pieces to enable the solar power to connect to the fans as well as the cooling mechanism to proliferate across the entire device.

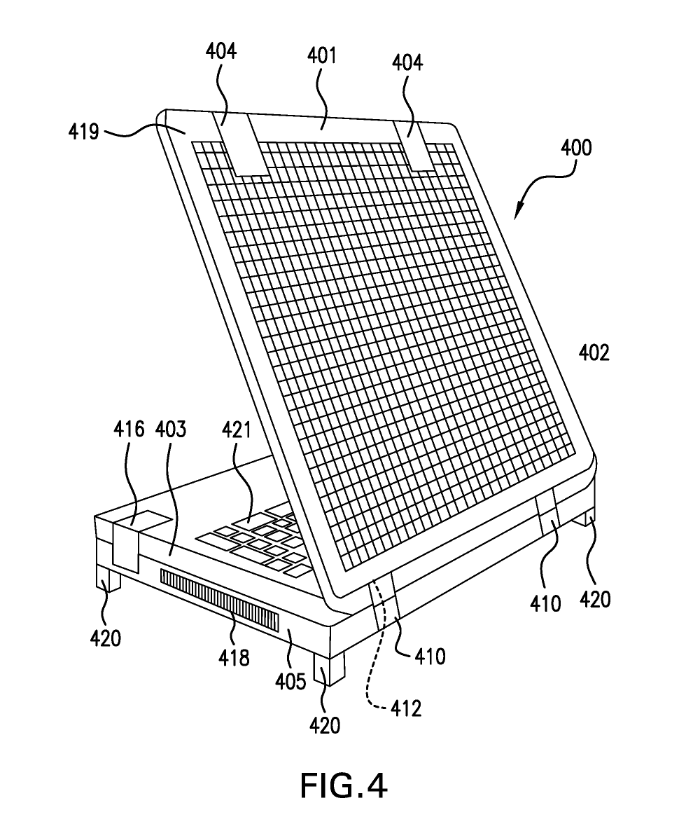

FIG. 4 is a perspective view of an alternative embodiment 400 of the present invention. A laptop computer 403 is shown. In this embodiment, a solar panel 402 is affixed to the rear side of the display panel 419 of laptop 401 via fasteners 404. Fasteners 404 may be self-stick fasteners, hook-and-loop fasteners, or other suitable mechanism. Fastener connectors 410 may be affixed to the base of the laptop. The fastener connectors 410 may be comprised of a flexible material, allowing the laptop to be folded for transport. One of the connectors 410 may also serve as a conduit for wires 412 which transport electricity generated by the solar panel 402 to the fans of the lower component 405. In embodiments, the lower component 405 may be fastened to the base portion (portion with the keyboard 421) of laptop computer 403 via one or more fasteners 416. Fasteners 416 may include self-stick adhesive fasteners, hook-and-loop fasteners, or other suitable mechanism. Lower component 405 may include a plurality of standoffs 420 at the bottom to raise the lower portion slightly, allowing airflow underneath the lower component. In embodiments, the standoffs 420 may have a height ranging from about 5 millimeters to 15 millimeters. The lower component 405 may include one or more side vents 418 to facilitate additional airflow. This embodiment does not cover the screen. This is suitable for laptops that have a touch screen, where the user wishes to interact directly with the laptop screen in a tactile manner. This embodiment also does not cover the keyboard, enabling the user to interact directly with the laptop keyboard in a tactile manner.

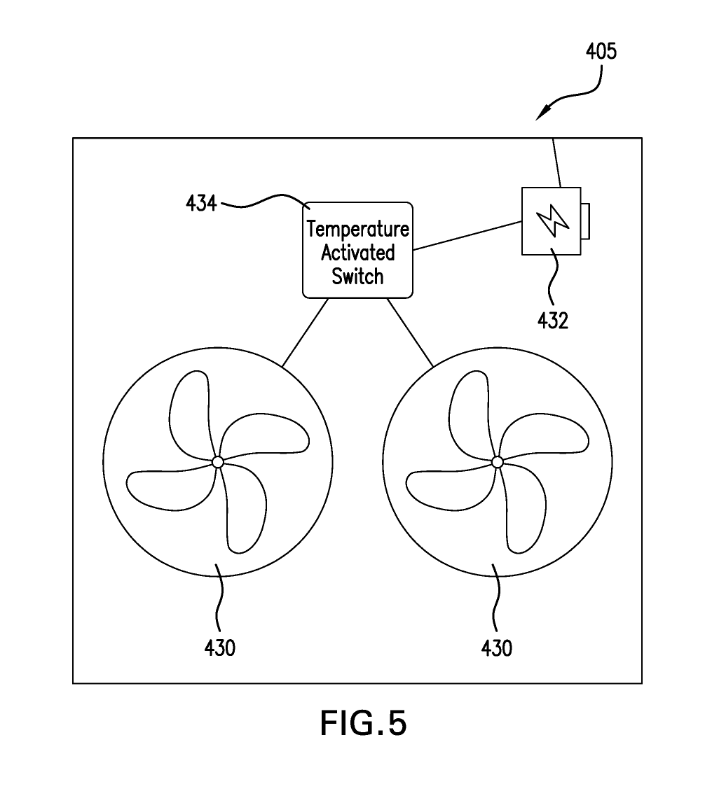

FIG. 5 is a schematic view of a lower component 405 of an alternative embodiment of the present invention. Lower component 405 includes one or more fans (indicated as 430). While two fans are shown in FIG. 5, other embodiments may include more or fewer fans. In embodiments, a rechargeable battery 432, such as a nickel cadmium battery or lithium ion battery is charged by the solar panel. A temperature activated switch 434 is configured and disposed to activate the fans 430 when the temperature detected by switch 434 exceeds a predetermined level. In embodiments, the temperature activated switch 434 is configured and disposed to activate the fans 430 when the detected temperature reaches a threshold ranging from about 50 degrees Celsius to about 75 degrees Celsius. When the detected temperature is below the predetermined threshold, the solar panel charges the battery 432. When the temperature exceeds the predetermined threshold, the temperature activated switch 434 activates to allow the battery 432 to power the fans, thereby cooling the laptop it is coupled to.

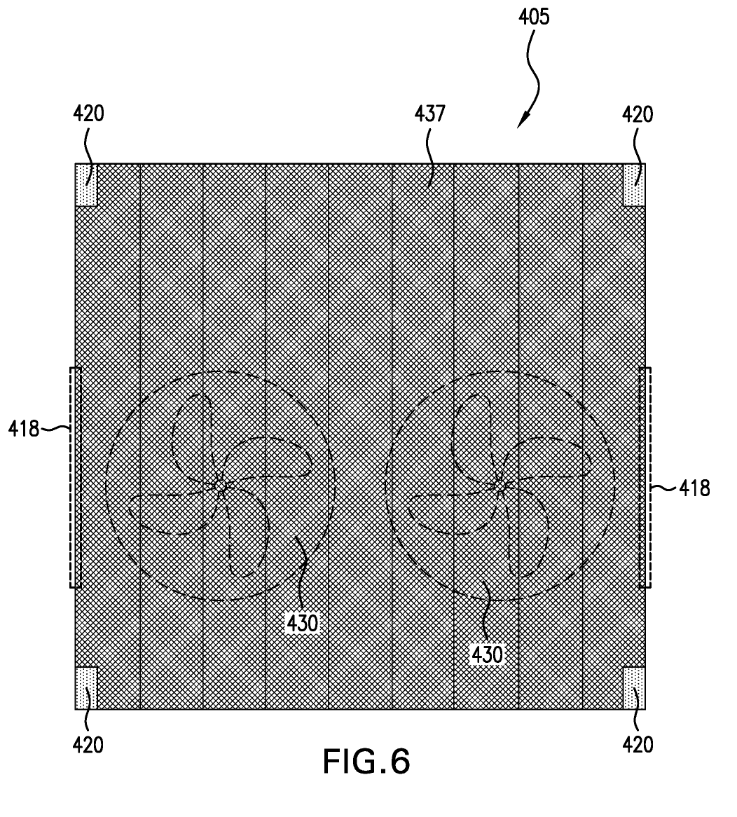

FIG. 6 is a bottom-up view of a lower component of an alternative embodiment of the present invention. Lower component 405 includes standoffs 420 which elevate the lower portion above a desk, table, or other flat surface where the laptop may be used. As can be seen in this view, a side vent 418 is disposed on each side of the lower component. A perforated surface 437 may be disposed on the bottom portion to allow airflow, while still covering the fans 430 (shown in dotted lines).

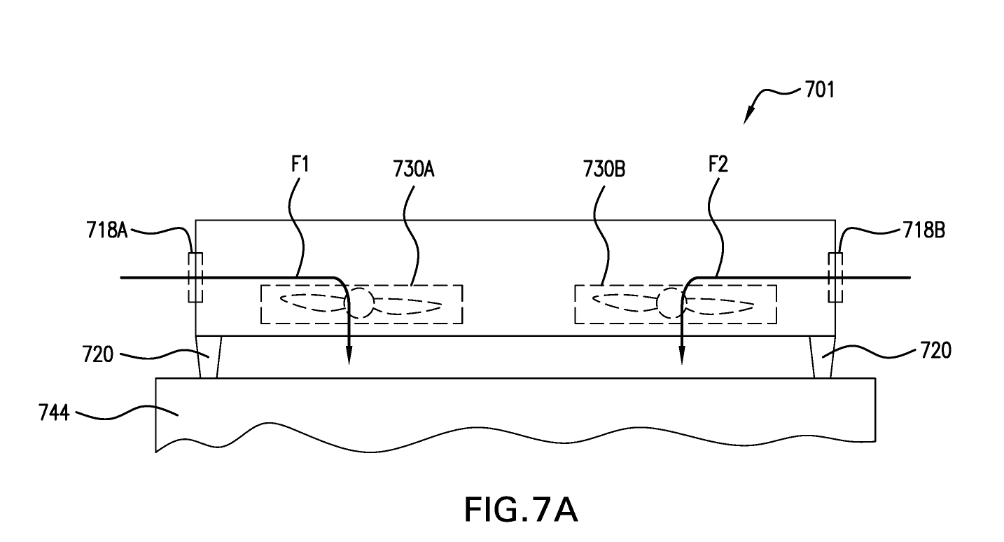

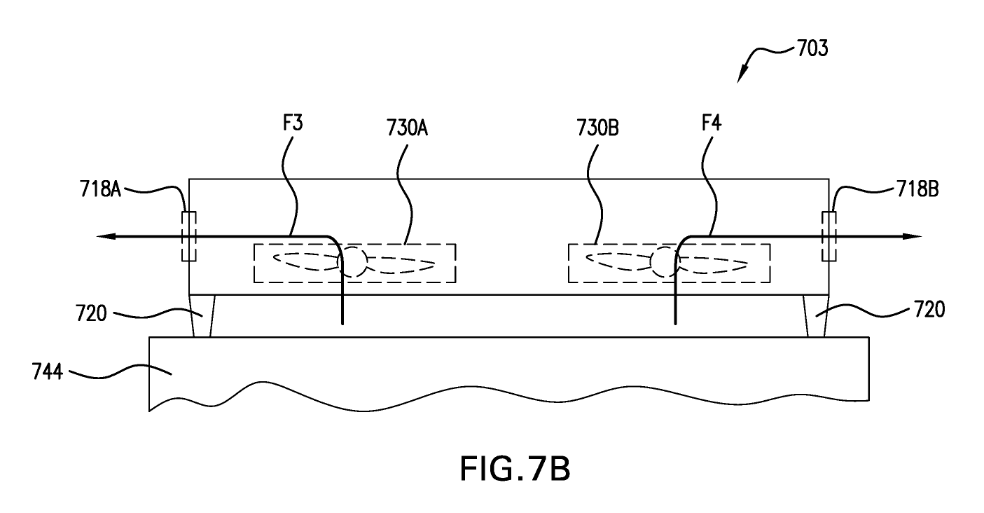

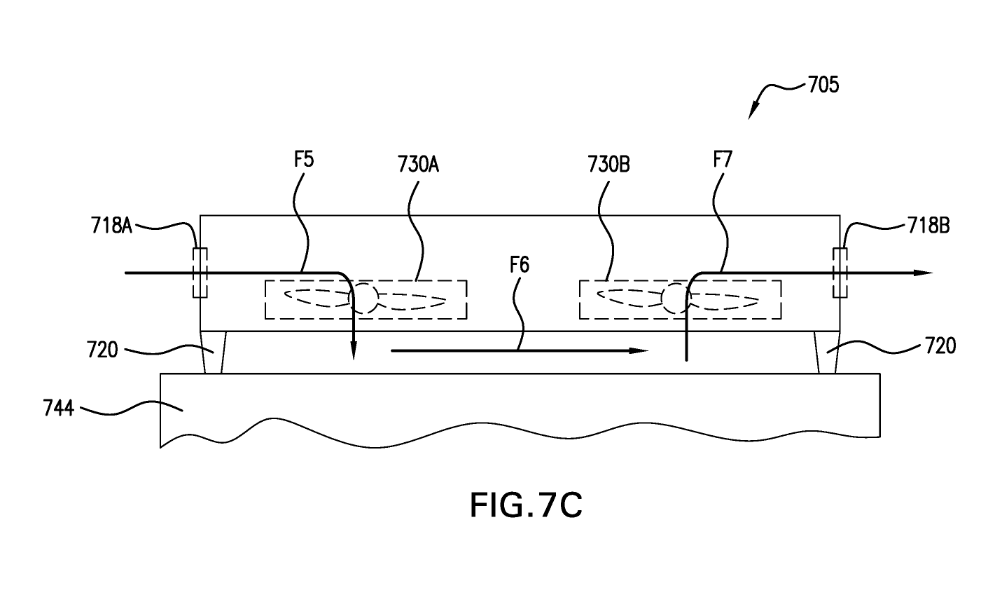

FIG. 7A is a side cutaway view of a lower component 701 of an alternative embodiment of the present invention configured for convergent airflow. In this configuration, fan 730A and fan 730B are both configured to provide downward flow. This creates airflow F1 drawing air through side vent 718A and downward, exiting below the lower portion, as indicated by airflow arrow F1. Standoffs 720 elevate the apparatus above desk 744, allowing for airflow. The air exiting the lower component 701 carries away excess heat, promoting laptop operation within a proper temperature range. Similarly, fan 730B draws air through side vent 718B, and pushes the air towards the desk 744, as indicated by airflow arrow F2. Thus, embodiments comprise a first fan and a second fan, wherein the first fan and second fan are both configured to push air out of the side vents.

FIG. 7B is a side cutaway view of a lower component 703 of an alternative embodiment of the present invention configured for divergent airflow. In this embodiment, fan 730A is configured to draw air from below the lower component, and push the air out of side vent 718A, as indicated by arrow F3. Similarly, fan 730B is configured to draw air from below the lower component, and push the air out of side vent 718B, as indicated by arrow F4. Thus, embodiments comprise a first fan and a second fan, wherein the first fan and second fan are both configured to push air out of the side vents.

FIG. 7C is a side cutaway view of a lower component 705 of an alternative embodiment of the present invention configured for pass-through airflow. In this embodiment, fan 730A is configured to pull air into side vent 718A and push it downward towards desk 744, as indicated by airflow arrow F5. Some of the air pushed out by fan 730A may be drawn back into lower component 705 by fan 730B, as indicated by airflow arrow F6 and airflow arrow F7. Fan 730B is configured in an opposite polarity to fan 730A, such that fan 730B is configured to draw air into the lower component 705, and the air is then pushed out of side vent 718B. In this way, air is drawn in one side of the lower portion at side vent 718A, and expelled through the opposite side vent 718B. Thus, embodiments comprise a first fan and a second fan, wherein the first fan is configured to draw air into one of the side vents and wherein the second fan is configured to push air out of one of the side vents.

Other configurations are possible to allow additional airflow schemes. Additionally, while disclosed embodiments illustrate fans with four blades, other fan blade configurations are possible, including, but not limited to, two blade fans, three blade fans, and/or five blade fans. The speed of the fans may be fixed, or in some embodiments, may vary based on temperature. In embodiments, the fan speed may be in the range of 200 revolutions per minute to 3,000 revolutions per minute.

As can now be appreciated, disclosed embodiments provide an improved cooling system for laptop computers. Solar cells mounted on the back of the display provide energy for operating one or more fans disposed below the laptop, creating additional airflow to help keep the laptop computer operating within a desired temperature range. Laptop computers are common amongst workers, students, and general home use. Thus, disclosed embodiments are uniquely positioned to target people of all ages, genders, and ethnicities. Disclosed embodiments support global trends such as finding alternative sources of energy that are clean and pure (i.e. solar energy that creates no waste or emissions). Additionally, aside from the ecological impact, more and more communities are engaging in flexible working, whether that be big corporations or entrepreneurs creating their own companies. Disclosed embodiments enable people to work almost anywhere. Furthermore, from a young age, most people are encouraged to spend more time outdoors, and disclosed embodiments give a person the opportunity to do so. Consequently, whether you're a university student who wishes to study on the campus lawn, an engineer in Palo Alto who wishes to enjoy the nice weather while coding, a parent who has to play DJ for a game of freeze dance for their child's birthday party in their backyard, or a photographer on safari who even with shade can't avoid heat, disclosed embodiments can provide additional cooling that can serve to improve the reliability of laptop computer operation in such situations.

When introducing elements of the present disclosure or the embodiment(s) thereof, the articles “a,” “an,” and “the” are intended to mean that there are one or more of the elements. Similarly, the adjective “another,” when used to introduce an element, is intended to mean one or more elements. The terms “including” and “having” are intended to be inclusive such that there may be additional elements other than the listed elements.

Although this invention has been described with a certain degree of particularity, it is to be understood that the present disclosure has been made only by way of illustration and that numerous changes in the details of construction and arrangement of parts may be resorted to without departing from the spirit and the scope of the invention.

What is claimed is:

1. A laptop computer cooling system, comprising:
a solar panel, the solar panel attachable to a rear side of a display of a laptop computer;
a fan enclosure, the fan enclosure attachable to a base portion of the laptop computer;
wherein the fan enclosure comprises one or more fans configured to operate from power provided by the solar panel.

2. The system of claim 1, wherein the fan enclosure comprises two fans.

3. The system of claim 1, wherein each fan of the fan enclosure comprises four blades.

4. The system of claim 1, wherein the fan enclosure further comprises a rechargeable battery, configured and disposed to receive power from the solar panel, and to provide power to each fan of the fan enclosure.

5. The system of claim 4, wherein the rechargeable battery comprises a nickel cadmium battery.

6. The system of claim 4, wherein the rechargeable battery comprises a lithium ion battery.

7. The system of claim 4, further comprising a temperature activated switch, configured and disposed to activate each fan of the fan enclosure upon detecting a temperature above a predetermined threshold.

8. The system of claim 7, wherein the predetermined threshold is a temperature ranging from 50 degrees Celsius to 75 degrees Celsius.

9. The system of claim 2, further comprising one or more side vents disposed in the fan enclosure.

10. The system of claim 9, further comprising a perforated surface disposed on a bottom surface of the fan enclosure.

11. The system of claim 2, wherein the two fans are configured to rotate at a speed ranging from 200 revolutions per minute to 3,000 revolutions per minute.

12. The system of claim 9, wherein the two fans comprise a first fan and a second fan, and wherein the first fan and second fan are both configured to draw air into the side vents.

13. The system of claim 9, wherein the two fans comprise a first fan and a second fan, and wherein the first fan and second fan are both configured to push air out of the side vents.

14. The system of claim 9, wherein the two fans comprise a first fan and a second fan, wherein the first fan is configured to draw air into one of the side vents and wherein the second fan is configured to push air out of one of the side vents.

15. A cooling case for a laptop comprising:
two parts;
wherein the parts are made of plastic material;
a cooling fan;
solar panels as the only source of power; and
tubular clips to connect the two parts.
